(19) United States
(12) Patent Application Publication
(10) Pub. No.: US 2026/0023890 A1
(43) Pub. Date: Jan. 22, 2026

(54) TECHNIQUES FOR LEVEL-SET BASED SHAPE OPTIMZIATION WITH SHAPE CONSTRAINTS

(71) Applicant: AUTODESK, INC., San Francisco, CA (US)

(72) Inventors: Alexander TESSIER, Toronto (CA); Adrian Stewart HUMPHRY, Toronto (CA); Adrian BUTSCHER, Toronto (CA); Mehran EBRAHIMI, Toronto (CA); Nigel Jed Wesley MORRIS, Toronto (CA)

(21) Appl. No.: 19/193,736

(22) Filed: Apr. 29, 2025

Related U.S. Application Data
(60) Provisional application No. 63/673,442, filed on Jul. 19, 2024.

(51) Int. Cl. G06F 30/17

(52) U.S. Cl. CPC G06F 30/17

(57) ABSTRACT

Techniques for level-set based shape optimization with shape constraints include simulating a state of a current shape of a component, calculating a sensitivity of an objective function to with respect to modification to the current shape based on the simulated shape based on the simulated state, generating a source function for an optimization equation based on the sensitivity, adding one or more constraint terms to the optimization equation based on one or more constraints on an interface of the shape to generate a constrained optimization equation, solving the constrained optimization equation to generate a solution to the constrained optimization equation, updating a velocity field based on the solution to the constrained optimization equation, solving a transport function based on the updated velocity field to generate a solution of the transport equation, and updating the current shape based on the solution to the transport equation to generate an updated shape.

### CROSS-REFERENCE TO RELATED APPLICATIONS

The present application claims the benefit of U.S. Provisional Application titled, “TECHNIQUES FOR LEVEL-SET BASED TOPOLOGY OPTIMIZATION WITH CONSTRAINED SHAPE,” filed on Jul. 19, 2024, and having Ser. No. 63/673,442. The subject matter of this related application is hereby incorporated herein by reference.

### BACKGROUND

### Field of the Various Embodiments

Embodiments of the present disclosure relate computer science and complex software and, more specifically, to techniques for level-set based shape optimization with shape constraints.

### Description of the Related Art

Designers use topology optimization techniques to design load-bearing and other structural components for a set of given physical and geometric objectives and constraints within a larger mechanical assembly. Topology optimization methods are able to achieve optimality through an iterative process of updating the shape of the component until a measure of the component's performance reaches a sufficient level of optimization. The structural components typically function as part of larger assemblies, where interfaces (welded connections, circular attachment points, joints, etc.) impose geometric and functional constraints between the component being optimized and other components within the assembly. These interfaces typically allow a limited subset of relative motions between the components, and the function of the interfaces should be retained during the optimization methods.

One technique for topology optimization is level-set topology optimization. Level-set topology optimization employs a level-set function to represent the boundary of the component, allowing for iterative changes to the level set-function as the component is optimized. With level-set topology optimization, a sensitivity analysis is performed to determine the best direction to adjust the component so as to help optimize an objective function. With each optimization iteration of the shape, a velocity field is constructed over the design space and the level-set function is transported along the velocity field to update the shape of the component.

Conventional level-set topology optimization techniques make free-form changes to the geometry of a component to achieve optimality. However, not all the portions of a component can or should be changed, such as the portions that form an interface with another component. For example, an interface that is part of a revolute joint that allows relative rotation should remain cylindrical in shape so that the optimized component can rotate about the interface. As another example, an interface to be welded may need to remain flat to permit welding to a matching interface in another component. To preserve the interfaces, a designer can keep regions of the component forming the interfaces completely fixed. One drawback of completing fixing an interface, prevents the portions of the component that form the interface from being optimized and participating in the optimization of the shape of the component.

Another drawback of existing techniques is that portions of the component where boundary conditions are defined, (e.g., where a fixed or constrained portion of an interface meets a free-form portion) cannot be smoothly incorporated into the optimization. Conventional techniques are not able to optimize these boundary conditions so that the boundary conditions allow for the constrained interface on one side of the boundary while allowing for flexibility on the free-form portion on the other side and while retaining a smoothness to the transition.

As the foregoing illustrates, what is needed in the art are more effective techniques for level-set based topology optimization with shape constraints.

### SUMMARY

According to some embodiments, a computer-implemented method for optimizing a shape of a component includes simulating a state of a current shape of the component; calculating a sensitivity of an objective function for the shape with respect to modifications to the current shape based on the simulated state; generating a source function for an optimization equation based on the sensitivity; adding one or more constraint terms to the optimization equation to generate a constrained optimization equation; solving the constrained optimization equation to generate a solution to the constrained optimization equation; updating a velocity field based on the solution to the constrained optimization equation; solving a transport function based on the updated velocity field to generate a solution of the transport equation; and updating the current shape based on the solution to the transport equation to generate an updated shape.

One technical advantage of the disclosed techniques relative to the prior art is that the disclosed techniques enable free-form optimization of non-interface regions of a component while allowing interface regions of the component to be modified in a manner that does not affect the functionality of the interface. These techniques allow more portions of a component (e.g., the interfaces) to be modified during optimization. As a result, the disclosed techniques result in components having a higher level of optimization than components optimized using conventional techniques. The higher level of optimization results in components that are cheaper and lighter than components optimized using conventional techniques. Moreover, the disclosed techniques ensure that different types of interfaces can adhere to different types of constraints, allowing the component being optimized to retain a desired function within a larger assembly. Another technical advantage of the disclosed techniques is that the boundary between the constrained interface and the free-form region is updated in a method that produces a smooth, gradual transition rather than an abrupt change in geometry, which further improves the optimized component. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a system configured to implement one or more aspects of the present disclosure.

FIG. 2 illustrates a computing system configured to implement one or more aspects of various embodiments.

FIG. 3 illustrates an example multi-component assembly, according to various embodiments

FIG. 4 is an example of a comparison of optimization methods, according to various embodiments.

FIG. 5 sets forth a flow diagram of method steps for modifying a shape of a component, according to various embodiments.

FIG. 6 sets forth a flow diagram for modifying a shape, according to various embodiments.

FIG. 7 illustrates examples of shape optimization using different interface constraints, according to various embodiments.

FIG. 8 illustrates additional examples of shape optimization using different interface constraints, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### Example Computing System

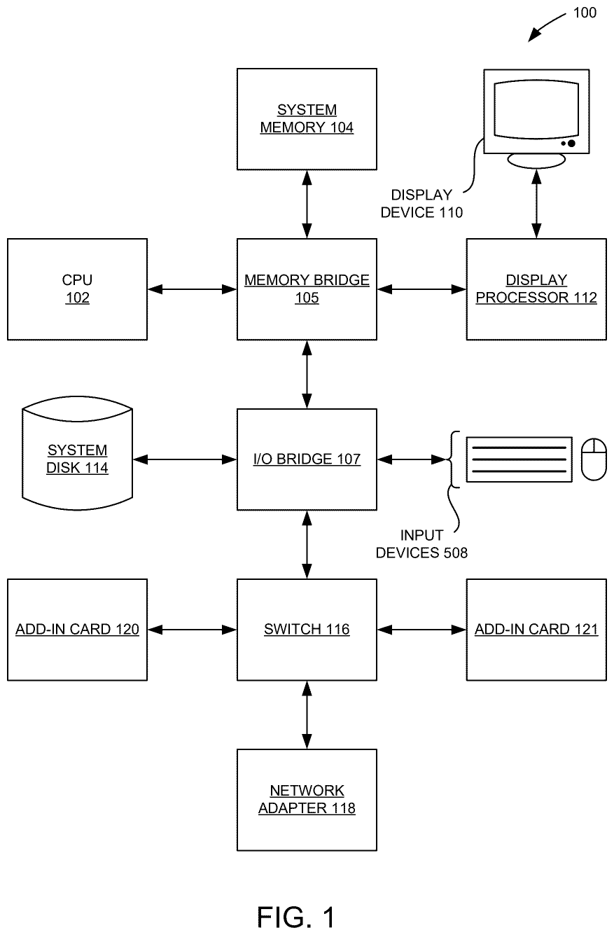

FIG. 1 is a block diagram of a system 100 configured to implement one or more aspects of the present disclosure. This figure in no way limits or is intended to limit the scope of the present disclosure. Further, in various embodiments, any combination of two or more systems 100 may be coupled together to practice one or more aspects of the present disclosure. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. V/O bridge 107, which may be, e.g., a Southbridge chip, receives user input from one or more user input devices 222 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, one or more of the various graphical user interfaces are displayed to one or more users via display device 110, and the one or more users can input data into and receive visual output from those various graphical user interfaces.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121.

Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114.

Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 incorporates circuitry optimized for graphics and video processing, including, for example, video output circuitry, and constitutes a graphics processing unit (GPU). In another embodiment, display processor 112 incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments of the present disclosure, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured to process data and execute program code. Such a processing device could be, for example, a central processing unit (CPU), a graphics processing unit (GPU), an application specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

Memory bridge 105 is further coupled to an I/O (input/output) bridge 107 via a communication path 106, and I/O bridge 107 is, in turn, coupled to a switch 116. As persons skilled in the art will appreciate, computer system 100 can be any type of technically feasible computer system, including, without limitation, a server machine, a server platform, a desktop machine, laptop machine, or a handheld/mobile device.

In operation, I/O bridge 107 is configured to receive user input information from input devices 222, such as a keyboard or a mouse, and forward the input information to CPU 102 for processing via communication path 106 and memory bridge 105. Switch 116 is configured to provide connections between I/O bridge 107 and other components of the computer system 100, such as a network adapter 118 and various add-in cards 120 and 121.

As also shown, I/O bridge 107 is coupled to a system disk 114 that can be configured to store content and applications and data for use by CPU 102 and parallel processing subsystem 112. As a general matter, system disk 114 provides non-volatile storage for applications and data and can include fixed or removable hard disk drives, flash memory devices, and CD-ROM (compact disc read-onlymemory), DVD-ROM (digital versatile disc-ROM), Bluray, HD-DVD (high definition DVD), or other magnetic, optical, or solid state storage devices. Finally, although not explicitly shown, other components, such as universal serial bus or other port connections, compact disc drives, digital versatile disc drives, film recording devices, and the like, can be connected to I/O bridge 107 as well.

In various embodiments, memory bridge 105 can be a Northbridge chip, and I/O bridge 107 can be a Southbridge chip. In addition, communication paths 106 and 113, as well as other communication paths within computer system 100, can be implemented using any technically suitable protocols, including, without limitation, AGP (Accelerated Graphics Port), HyperTransport, or any other bus or point-to-point communication protocol known in the art.

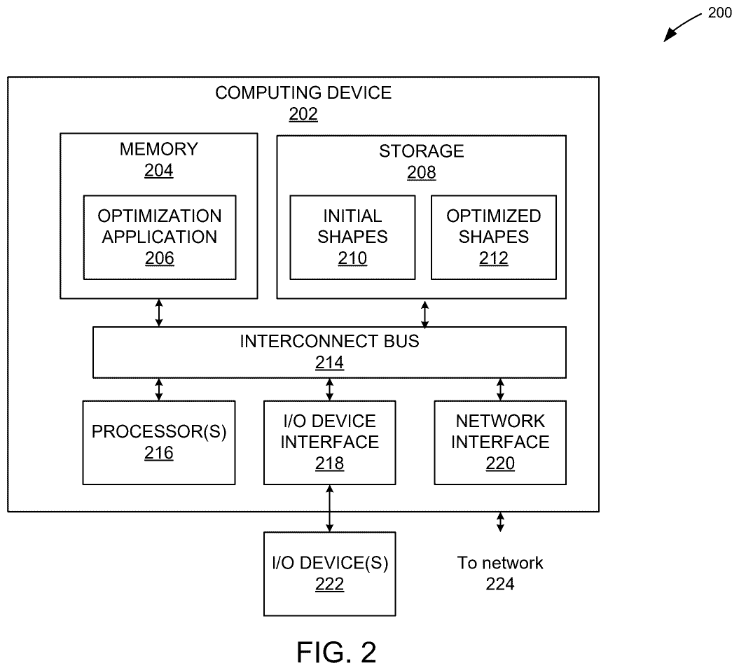

In some embodiments, parallel processing subsystem 112 comprises a graphics subsystem that delivers pixels to a display device 110 that can be any conventional cathode ray tube, liquid crystal display, light-emitting diode display, or the like. In such embodiments, the parallel processing subsystem 112 incorporates circuitry optimized for graphics and video processing, including, for example, video output circuitry. As described in greater detail below in FIG. 2, such circuitry can be incorporated across one or more parallel processing units (PPUs) included within parallel processing subsystem 112. In other embodiments, the parallel processing subsystem 112 incorporates circuitry optimized for general purpose and/or compute processing. Again, such circuitry can be incorporated across one or more PPUs included within parallel processing subsystem 112 that are configured to perform such general purpose and/or compute operations. In yet other embodiments, the one or more PPUs included within parallel processing subsystem 112 can be configured to perform graphics processing, general purpose processing, and compute processing operations. System memory 104 includes at least one device driver 103 configured to manage the processing operations of the one or more PPUs within parallel processing subsystem 112.

It will be appreciated that the system shown herein is illustrative and that variations and modifications are possible. The connection topology, including the number and arrangement of bridges, the number of CPUs 102, and the number of parallel processing subsystems 112, can be modified as desired. For example, in some embodiments, system memory 104 could be connected to CPU 102 directly rather than through memory bridge 105, and other devices would communicate with system memory 104 via memory bridge 105 and CPU 102. In other alternative topologies, parallel processing subsystem 112 can be connected to I/O bridge 107 or directly to CPU 102, rather than to memory bridge 105. In still other embodiments, I/O bridge 107 and memory bridge 105 can be integrated into a single chip instead of existing as one or more discrete devices. Lastly, in certain embodiments, one or more components shown in FIG. 1 may not be present. For example, switch 116 could be eliminated, and network adapter 118 and add-in cards 120, 121 would connect directly to I/O bridge 107.

### System Overview

FIG. 2 illustrates a computing system 200 configured to implement one or more aspects of various embodiments. As shown, computing system 200 includes, without limitation, a computing device 202, input/output device(s) 222, and a network 224. Computing device 202 includes, without limitation, memory 204, storage 208, an interconnect bus 214, one or more processors 216, an input/output (I/O) device interface 218, and a network interface 220. Memory 204 includes, without limitation, an optimization application 206. Storage 208 includes, without limitation, initial shapes 210 and optimized shapes 212.

In some embodiments, computing device 202 can be a desktop computer, a laptop computer, a smart phone, a personal digital assistant (PDA), tablet computer, or any other type of computing device configured to receive input, process data, and optionally display images, and is suitable for practicing one or more embodiments. Illustratively, computing device 202 is configured to run optimization application 206.

It is noted that the computing device 202 described herein is illustrative and that any other technically feasible configurations fall within the scope of the present disclosure. For example, computing device 202 could be implemented as part of system 100. In some embodiments, any combination of the components in computing device 202 (e.g., process(s) 216, memory 204, etc.) can be replaced with components within any type of virtual computing system, distributed computing system, or cloud computing environment, such as a public cloud, a private cloud, or a hybrid cloud.

Processor(s) 216 can be any suitable processor implemented as a central processing unit (CPU), a graphics processing unit (GPU), an application-specific integrated circuit (ASIC), a field programmable gate array (FPGA), an artificial intelligence (Al) accelerator, any other type of processing unit, or a combination of different processing units, such as a CPU configured to operate in conjunction with a GPU. In general, processor(s) 216 may be any technically feasible hardware unit capable of processing data and/or executing software applications. Further, in the context of this disclosure, the computing elements shown in computing device 202 can correspond to a physical computing system (e.g., a system in a data center) or can be a virtual computing instance executing within a computing cloud.

Interconnect bus 214 is configured to serve as a communication conduit interconnecting individual components within computing device 202. In some embodiments, interconnect bus 214 couples memory 204, storage 208, processor(s) 216, I/O device interface 218, and network interface 220, in addition to any other elements required by a particular embodiment of the system. Interconnect bus 214 can be implemented using wired connections, and in certain embodiments, interconnect bus 214 is also capable of accommodating wireless communication between the interconnected components if needed.

I/O devices 222 include devices capable of providing input, such as a keyboard, a mouse, a touch-sensitive screen, and so forth, as well as devices capable of providing output, such as a display device. Additionally, I/O devices 222 can include devices capable of both receiving input and providing output, such as a touchscreen, a universal serial bus (USB) port, and so forth. I/O devices 222 can be configured to receive various types of input from an end-user (e.g., a designer) of computing device 202, and to also provide various types of output to the end-user of computing device 202, such as displayed digital images or text. In some embodiments, one or more of I/O devices 222 are configured to couple computing device 202 to a network 224.

I/O device interface 218 is configured to facilitate the connection of one or more I/O devices 222 to computing device 202. In some embodiments, I/O device interface 218 is able to interface with different input modalities from I/O devices 222 as needed. For example, the interface may include USB or Thunderbolt ports for wired peripherals like, HDMI or DisplayPort outputs for displays, and wireless interfaces such as Bluetooth or Wi-Fi modules for contactless communication. Other examples include interface protocols such I2C or SPI, MIPI DSI or LVDS for displays, parallel interfaces for legacy devices, and serial interfaces for point-to-point communications.

Network 224 is any technically feasible type of communications network that allows data to be exchanged between computing device 202 and external entities or devices, such as a web server or another networked computing device. For example, network 224 can include a wide area network (WAN), a local area network (LAN), a wireless (WiFi) network, and/or the Internet, among others.

Network interface 220 is configured to comprise any reasonable combination of devices required to facilitate communication between network 224 and computing device 202. In some embodiments, network interface 220 may incorporate hardware necessary for various communication protocols, including but not limited to wireless, Bluetooth, wide area network (WAN), local area network (LAN), and Wi-Fi connectivity.

Storage 208 includes non-volatile storage for applications and data, and can include fixed or removable disk drives, flash memory devices, and CD-ROM, DVD-ROM, Blu-Ray, HD-DVD, or other magnetic, optical, or solid-state storage devices. Optimization application 206 can be stored in storage 208 and loaded into memory 204 when executed. As shown,, storage 208 also includes initial shapes 210 and optimized shapes 212.

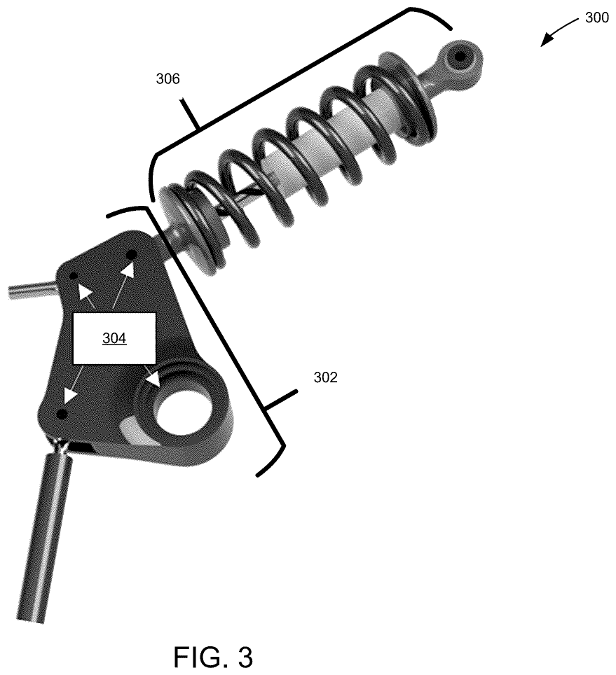

In some embodiments, initial shapes 210 correspond to components within an assembly that are selected for optimization. Initial shapes 210 can include, without limitation, various interfaces configured to couple with interfaces of other components of the assembly. In some embodiments, an interface corresponds to a region of a component that mates with a corresponding region on another component within an assembly. For example, interfaces can include welded connections, which often require a flat geometry for manufacturability, or rotational joint connections that include a cylindrical profile to permit uni-axial rotational motion. FIGS. 3, 4, 7, and 8 provide additional examples of such interfaces. The interfaces can be subject to constraints, enabling the interfaces to experience affine motions such as translation, rotation, and orthotropic scaling. The interface constraints are sometimes referred to as affine constraints. Such constraints allow the interfaces to continue to perform a desired function while still being adjusted during optimization by optimization application 206. For example, an interface can translate or uniformly scale while maintaining a cylindrical or flat form. Initial shapes 210 can be generated in any technically suitable fashion, such as using a computer-aided design (CAD) application and then saved in storage 208

In some embodiments, a shape or geometry of a component is described implicitly by a level-set function defined over a design domain D⊆ [symbol] ³. Specifically, a scalar function F: D→ [symbol] represents the shape, wherein the component is defined as the zero sub-level set {x∈D: F(x)≤0}. A canonical representation of F is the signed distance function, which assigns negative values for points within the shape and positive values for points outside the shape, ensuring Lipschitz continuity and ∥IDF(x)∥=1 almost everywhere. Initial shapes 210 are accessed by optimization application 206. Although shown as stored in storage 208, initial shapes 210, and optimized shapes 212 can be stored elsewhere, such as in memory 204, in a storage system coupled to computing device 202 via network 224, and/or the like. Examples of possible initial shapes 210 are shown in FIGS. 3, 4, 7, and 8.

Optimized shapes 212 are generated by optimization application 206 in response to optimizing corresponding initial shapes 210. Each of optimized shapes 212 are optimized relative to the corresponding initial shapes 210 subject to one or more constraints on the corresponding initial shapes 210 that preserve the functionality of the various interfaces. Although shown as stored in storage 208, optimized shapes 212 can be stored elsewhere, such as in memory 204, a network-coupled storage system coupled to computing device 202 via network 224, and/or the like.

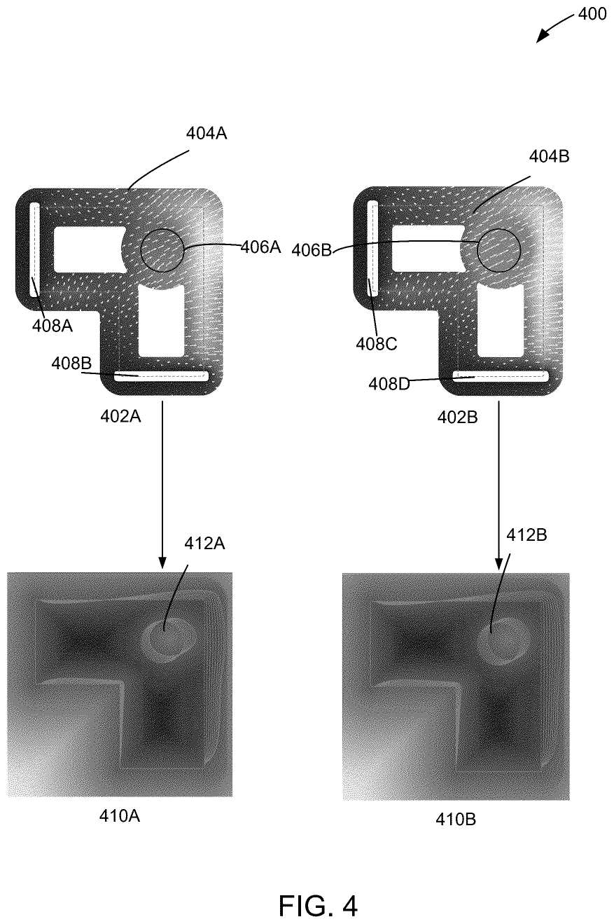

Memory 204 includes a random-access memory (RAM) module, a flash memory unit, or any other type of memory unit or combination thereof. Processor(s) 102, I/O device interface 218, and network interface 220 are configured to read data from and write data to memory 204. Memory 204 includes various software programs that can be executed by processor(s) 102 and application data associated with said software programs, including optimization application 206. Examples of possible optimized shapes 210 are shown in FIGS. 4, 7, and 8.

Optimization application 206 resides in memory 204 and executes on processor(s) 216 of computing device 202. Additionally, optimization application 206 could also be stored in storage 208 and then loaded into memory 204 for execution by processor(s) 216. In operation, optimization application 206 performs an optimization process on each of initial shapes 210 to generate corresponding optimized shapes 212.

Optimization application 206 begins by receiving an initial shape 210 that is to be optimized. Optimization application 206 reads initial shape 210 from storage 208. Optimization application 206 then represents initial shape 210 using a level-set function, which is the set of all points where the field is less than or equal to zero. Optimization application 206 then identifies and defines interfaces and the respective constraints on those interfaces, as determined by the designer. Specifically, optimization application 206 identifies interfaces as specific, disjoint portions of the shape boundary through which the component interacts with other components in an assembly. Optimization application 206 then defines interfaces by partitioning the overall boundary into a plurality of disjoint subsets, where each subset can correspond to an interface. Optimization application 206 then assigns each interface a spatial location parameter p, (where p∈ [symbol] ³) and an orientation parameter Q, (where Q∈ [symbol] ^{3×3}) sufficient to locate the interface in space. To preserve the geometric properties of these interfaces during shape optimization, optimization application 206 constrains the allowable motions of each interface within a small tubular neighborhood surrounding that interface. Specifically, the interface regions are restricted to allow only affine motions. More specifically, the allowed affine motions ϕ are implemented by composing one or more of a translation defined by a vector y∈ [symbol] ³, a rotation about a fixed point p by an axis defined by h∈ [symbol] ³, and/or a scaling defined by scaling factors d∈ [symbol] ³, as defined by Equation 1. In Equation 1, x∈ [symbol] ³ denotes a point in the design domain, p∈ [symbol] ³ is the spatial location parameter that defines a fixed point at which the interface is positioned, Q∈ [symbol] ^{3×3} is the orientation parameter, an orthonormal matrix that specifies the alignment of the interface in space, t∈ [symbol] ³ represents the translation vector indicating the direction and magnitude of the translation, and h∈ [symbol] ³ defines the axis about which rotation occurs.

Optimization application 206 computes the corresponding antisymmetric matrix A(h) from h so that exp(εA(h)) yields the rotation component for a small parameter ε. h is a vector in [symbol] ³ that parameterizes the rotation component of the deformation, encoding both the axis and the magnitude of the rotation. Furthermore, d∈ [symbol] ³ is a vector of scaling factors, which is arranged into a diagonal matrix D=diag(d) so that exp(εD) provides the scaling component. ε is a small scalar parameter representing the magnitude of the deformation.

Optimization application 206 then expresses the compound motion of the interface using Equation 1, where the individual transformations are defined by:

$$\begin{matrix}{ϕ\_trans}_{ε} ( x ) = x + ε t , \\ {ϕ\_rot}_{ε} ( x ) = exp ( ε A ( h ) ) \cdot ( x - p ) + p , and \\ {ϕ\_scal}_{ε} ( x ) = Q \cdot exp ( ε D ) \cdot {Q}^{⊤} \cdot ( x - p ) + p .\end{matrix} \qquad ( 1 )$$

$$\begin{matrix}{ϕ}_{ε}^{allowed} ( x ) := {ϕ}_{ε}^{trans} ◦ {ϕ}_{ε}^{rot} ◦ {ϕ}_{ε}^{scal} ( x ) \\ = exp ( ε ( h ) ) exp ( ε D ) {⊤}^{} ( x - p ) + p + ε t\end{matrix}$$

This compound motion forms a linear combination of the individual allowed motions, ensuring that any permitted interface deformation falls within a finite-dimensional space of affine transformations.

Optimization application 206 then iteratively performs optimization steps on initial shape 210 until a corresponding optimized shape 212 is achieved. Optimization application 206 is described below primarily in the context of shape compliance minimization. However, the person of ordinary skill would understand that the disclosed techniques are equally applicable to other shape optimization problems. Specifically, shape optimization problems for which the sensitivity of the objective function to shape changes can be represented in a form that has as an integral over the boundary that involves a shape gradient term and the normal component of the deformation. During each iteration, optimization application 206 first simulates the state of the current shape based on an elastic response and a corresponding strain when the shape is under a load. Optimization application 206 then uses the simulation results to calculate sensitivities of the objective function with respect to the shape modifications based on the state of the shape, quantifying how small shape modifications affect the objective function. For example, the objective function can measure structural compliance (e.g., the strength-to-weight ratio) of the shape. The sensitivity calculation can be different for different types of minimizations but in general is computed based on state information (e.g. structural response), problem definition (e.g. location of loads) and in some cases, an adjoint solution. An adjoint solution is used for some objective types, but not for compliance minimization. The adjoint solution can include solving another PDE (likely using variational methods and/or finite element methods as well). Optimization application 206 then uses the sensitivity information to construct the source terms for a Constrained Hilbert Space Extension (CHSE) equation. Source terms are the forcing functions that incorporate the effects of local shape variations on performance. The source terms mathematically represent the distribution of sensitivity-derived influences that result in a velocity field representing possible modifications to the shape of the component. The CHSE equation is constructed to help compute a smooth, descent-directed velocity field that extends boundary sensitivity information into the design domain while satisfying the interface constraints.

Optimization application 206 then solves the CHSE equation by setting up the Hilbert space framework and constraining the solution space for the specified allowed affine motions. The solution to the CHSE equation captures the spatial variations in the evolving shape. Optimization application 206 uses the solution to the CHSE equation to construct an updated velocity field. Optimization application 206 applies the velocity field to a Hamilton-Jacobi transport equation, which optimization application 206 solves and uses the solution to update the level-set function and, ultimately, the shape. The optimization steps are described in further detail below.

Optimization application 206 can repeat the optimization process for different initial shapes 210 or for the same initial shape 210 subject to different interface constraints.

### Shape Optimization Steps

The shape or topology optimization steps in each iteration begin with optimization application 206 simulating the state of the shape using a chosen shape function. The shape function, which can be expressed as a volume or surface, corresponds to an elastic response un and a corresponding strain en when the shape is under a load.

Optimization application 206 computes the elastic response by solving a set of governing partial differential equations (PDEs) that ensures mechanical equilibrium and enforces the specified boundary conditions for the component. In particular the set of PDEs that describe the mechanical equilibrium and specified boundary conditions is expressed according to Equation 2. Equation 2 identifies the negative divergence of the stress tensor, -divσ(μ_{Ω}), which is equal to the load f applied to the shape. The boundary conditions indicate the restrictions on the interfaces of the shape and include both Dirichlet conditions on corresponding portions of the shape of the boundary (μ_{Ω}=0 on Γ_{D}) and Neumann conditions on corresponding portions of the shape (n·σ(μ_{Ω})=g on Γ_{N}). Initial shape 210 indicates the boundary conditions by physical requirements on the shape and the overall assembly. Optimization application 206 assigns portions of the boundary where the displacement is fully prescribed or fixed (such as where the component is rigidly attached or clamped) as Dirichlet boundary conditions. In contrast, optimization application 206 assigns boundaries where external forces or tractions are applied as Neumann boundary conditions. The determination of which segments receive Dirichlet or Neumann conditions is based on the specific load-bearing attachment, and support conditions dictated by the design and the function of the component as indicated in initial shape 210.

$$\begin{matrix}- div ( σ ( {u}_{Ω} ) ) = f & in Ω \\ {u}_{Ω} = 0 & on {Γ}_{D} ⊆ \partial Ω \\ {n}_{\partial Ω} \cdot σ ( {u}_{Ω} ) = g & on {Γ}_{N} ⊆ \partial Ω \\ {n}_{\partial Ω} \cdot σ ( {u}_{Ω} ) = 0 & on \partial Ω \text{\textbackslash (} {Γ}_{D} ⋃ {Γ}_{N} )\end{matrix} \qquad ( 2 )$$

Ω denotes the shape or design domain under consideration, I represents the boundary of the shape Ω which is further partitioned into disjoint portions for applying different boundary conditions, and σ(μ_{Ω}) is the stress tensor corresponding to the displacement field μ_{Ω} within the shape. The stress tensor is related to the response of the material under loading. The portion of the boundary of Ω where Dirichlet boundary conditions are imposed is denoted by Γ_{D}; that is, where the displacement μ_{Ω} is prescribed (e.g., set to zero). The portion of the boundary where Neumann boundary conditions are applied is denoted by Γ_{N}; that is, where the surface traction is specified with n·σ(μ_{Ω})=g on Γ_{N}, where g is the prescribed traction and n is the outward-pointing normal to the boundary.

Optimization application 206 then solves the set of PDEs from Equation 2. The solution to the set of PDEs represents the state of the current shape (e.g., the displacement, stress, etc. of the current shape) under the given loads. Using the state information in the solution to the set of PDEs, optimization application 206 then computes the shape derivative dΩ. The shape derivative quantifies the sensitivity of the objective function to small perturbations in the geometry of the shape (e.g., a rate at which the objective function changes as the shape is perturbed). Optimization application 206 uses the shape derivative to indicate the directions in which the level-set function could be updated to improve the geometry of the shape.

Optimization application 206 then performs a sensitivity analysis on the shape by computing how small changes in the shape affect the overall performance as measured by the objective function. In a general shape optimization problem, an initial goal is to determine the shape gradient which captures the sensitivity of the objective function to shape changes Θ_{ε}, as represented by Equation 3. n_{∂0} is the outward-pointing unit normal vector indicating the direction perpendicular to the boundary of the shape. Θ_{ε=0} is the infinitesimal update or deformation applied to the shape. As indicated by Equation 3, only the normal component of the shape perturbation causes changes to the objective function.

$$D {𝒥}_{Ω} ( {Θ}_{ε = 0} ) = {\int }_{\partial Ω} d {𝒥}_{Ω} {n}_{\partial Ω} \cdot {Θ}_{ε = 0} \qquad ( 3 )$$

To solve perform optimizations for shape compliance minimization, optimization application 206 uses Equation 4 to generate the shape gradient d [symbol] _{Ω}, which represents the sensitivity of the objective function to changes at each point on the boundary of the shape.

$$d {𝒥}_{comp , Ω} := \{ \begin{matrix}σ ( {u}_{Ω} ) : e ( {u}_{Ω} ) & on {Γ}_{fix} \\ - σ ( {u}_{Ω} ) : e ( {u}_{Ω} ) + 2 ( {H}_{\partial Ω} - \frac{\partial }{\partial n} ) ( g \cdot {u}_{Ω} ) + 2 f \cdot {u}_{Ω} & on {Γ}_{load} \\ - σ ( {u}_{Ω} ) : e ( {u}_{Ω} ) + 2 f \cdot {u}_{Ω} & on {Γ}_{free}\end{matrix} \qquad ( 4 )$$

In Equation 4, Ω is the shape or domain of the structure being optimized. Ω_{ε} is a perturbed version of this shape under a small deformation. μ_{Ω} is the displacement field within Ω, representing how the structure deforms under applied forces. σ(μ_{Ω}) is the stress tensor computed from this displacement, and e(μ_{Ω}) is the corresponding strain tensor. f is the body force per unit volume acting throughout Ω, and g is the surface traction (load per unit area) applied on the boundary Γ_{load}. Γ_{load} is the part of the boundary where loads are applied, Γ_{fix} is the part where the displacement is fixed (Dirichlet condition), and Γ_{free} is the remaining boundary that is free or unloaded. H_{∂Ω} is the mean curvature of the boundary ∂Ω, and ∂/∂n(g·u_{Ω}) is the normal derivative of the scalar field g·u_{Ω} on the boundary. [symbol] _{comp}(Ω) is the elastic compliance, which measures the elastic energy (or flexibility) of the structure under load, and d [symbol] _{comp,Ω} is the shape derivative of this compliance, representing how it changes under infinitesimal shape deformations.

In some embodiments, optimization application 206 performs a specialized sensitivity analysis for the elastic compliance of the shape. The elastic compliance measures a flexibility of the shape under applied loads. Compliance measures stress and strain experienced by the structure when subjected to forces. Compliance often provides an objective measure in structural optimization problems. Optimization application 206 computes the sensitivity of the compliance according to Equation 5, breaking down the contributions from different parts of the boundary, specifically fixed regions (Γ_{fix}), loaded regions (Γ_{load}), and free regions (Γ_{free}).

$$\frac{d}{d ε} {𝒥}_{comp} ( {Ω}_{ε} ) {\vert}_{ε = 0} = {\int }_{{Γ}_{fix}} σ ( {u}_{Ω} ) : e ( {u}_{Ω} ) {Θ}^{⊥} + {\int }_{{Γ}_{load}} ( - σ ( {u}_{Ω} ) : e ( {u}_{Ω} ) + 2 ( \frac{\partial }{\partial n} - {H}_{\partial Ω} ) ( g \cdot {u}_{Ω} ) + 2 f \cdot {u}_{Ω} ) {Θ}^{⊥} + {\int }_{{Γ}_{free}} ( - σ ( {u}_{Ω} ) : e ( {u}_{Ω} ) + 2 f \cdot {u}_{Ω} ) {Θ}^{⊥} \qquad ( 5 )$$

In Equation 5, [symbol] _{comp}(Ω_{ε}) is the elastic compliance of the shape Ω and is defined as the integral over the domain Q of the inner product of the stress and strain tensors. [symbol] _{comp}(Ω_{ε}) measures how much the structure deforms under the applied loads, where a lower compliance generally indicates a stiffer structure. Ω_{ε} is a perturbed version of the shape Ω, where ε is a small parameter controlling the magnitude of the deformation. The derivative d( [symbol] _{comp}(Ω_{ε})/dε|ε=0 represents the rate of change of compliance due to an infinitesimal deformation. μ_{Ω} is the displacement field solution of the linear elastic equations defined on the domain Ω. μ_{Ω} describes how each point in Q moves under the applied loads. σ(μ_{Ω}) is the stress tensor associated with the displacement field Ω_{ε}·σ(μ_{Ω}) is expressed as σ(μ_{Ω}):=A: e(μ_{Ω}), where A is the fourth-order, homogeneous, and isotropic elasticity tensor. e(μ_{Ω}) is the strain tensor corresponding to the displacement field μ_{Ω}. e(μ_{Ω}) quantifies the deformation (or strain) in the material. f is the body force distribution per unit volume acting on Ω (for example, gravitational forces). f: Ω→ [symbol] ³.

Furthermore, in Equation 5, g is the load distribution per unit area applied on the boundary portion where loads are imposed. g: Γ_{load}→ [symbol] . Γ_{fix} is the subset of the boundary ∂Ω, where Dirichlet boundary conditions (fixed displacements) are applied. Γ_{load} is the subset of the boundary ∂Ω where loads (represented by g) are applied. Γ_{free} is the remainder of the boundary of Ω, defined as Γ_{free}: =∂Ω\(Γ_{load}∪Γ_{fix}), where a zero-traction (Neumann) condition is assumed. n is the outward-pointing unit normal vector field on the boundary ∂Ω. n is used to define the direction perpendicular to the boundary. Θ^{⊥} is the normal component of the infinitesimal deformation vector field (Θ). Θ^{⊥} is typically given by the inner product of Θ with the normal vector n, i.e., Θ^{⊥}= [symbol] Θ, n [symbol] . In Equation 5, only the normal component contributes to the sensitivity of the compliance. H_{∂Ω} is the mean curvature of the boundary ∂Ω with respect to the outward-pointing normal. The mean curvature appears in the term (∂/∂n−H_{∂Ω}) (g·u_{Ω}) to account for geometric effects of the boundary when loads are applied. ∂/∂n (g·u_{Ω}) is the derivative of (g·u_{Ω}) taken in the direction of the unit normal vector n. d/dε [symbol] _{comp}(Ω_{ε})|ε=0 represents the shape derivative of the compliance with respect to the deformation parameter ε and quantifies how sensitive the compliance (performance measure) is to an infinitesimal change in the shape.

Optimization application 206 then constructs the source function that drives the shape toward an improved shape as evaluated using the objective function.

Optimization application 206 uses the shape derivative to provide information about how to improve the shape as measured by the objective function.

Optimization application 206 determines a relationship between the shape derivative and a Hilbert space gradient of the objective function using Equation 5. By using a Hilbert Space Extension (HSE) method, optimization application 206 is able to leverage the smoothing properties of a Sobolev space to extend and regularize boundary-derived sensitivity information for the shape. Using the HSE, optimization application 206 generates a smooth and physically plausible velocity field that serves as a descent direction for the shape optimization process that updates the shape.

Optimization application 206 can express the shape derivative using Equation 6 by choosing an appropriate inner product (denoted [symbol] [symbol] ., [symbol] [symbol] γ).

$$\begin{matrix}{〈 〈 {grad ( 𝒥 )}_{Ω} , Θ 〉 〉}_{γ} = {\int }_{\partial Ω} d {𝒥}_{Ω} {n}_{\partial Ω} \cdot Θ & ∀\end{matrix} Θ ∈ {H}_{0}^{1} ( ℬ , {ℝ}^{3} ) \qquad ( 6 )$$

In Equation 5, grad( [symbol] )_{Ω} is the Hilbert space gradient of the objective function [symbol] with respect to the domain Ω. grad( [symbol] )_{Ω} a vector field defined on the narrow band B (a tubular neighborhood around ∂Ω) that indicates the descent direction for the shape update. Equation 6 computes an inner product (denoted [symbol] [symbol] ., [symbol] [symbol] γ) between shape derivative grad( [symbol] )_{Ω} and vector field Θ.

In Equation 5, Θ is a test function against which the gradient is defined and is a vector field belonging to the Hilbert space H¹₀(B, [symbol] ³). In a variational formulation every vector field in H¹₀(B, [symbol] ³) qualifies as a test function. The variational formulation defines the Hilbert space gradient by equating the inner product of the gradient with an arbitrary test function to the behavior of the shape derivative. The candidate extension velocity field appears as the unique solution that satisfies this equality for every test function. The same vector field simultaneously serves as the candidate solution and as a representative test function because the equality holds for all elements in H¹₀(B, [symbol] ³). The Riesz representation theorem guarantees the existence and uniqueness of this candidate field.

B is the narrow band (a tubular neighborhood) around the shape's boundary (∂Ω) where the deformation is considered. B is chosen to capture the region of interest for the shape update while excluding non-design areas. H¹₀(B, [symbol] ³) is a Sobolev space of vector fields defined on B. In the Sobolev space, each vector field is square-integrable and has square-integrable first weak derivatives. Although the vector field may not be differentiable in the classical sense, the first derivatives of the vector field exist in a generalized (distributional) sense and the squares of the first derivatives are integrable over the set B. The vector field in the Sobolev space vanishes on Γ₀, meaning that the vector fields are zero on the portion of the boundary of B that contacts non-design regions, which ensures that deformations are only applied where desired.

[symbol] [symbol] ·, · [symbol] [symbol] y denotes the inner product on H¹₀(B, [symbol] ³). The inner product combines the L² norms of functions in H¹₀(B, [symbol] ³) with the L² norms of the first weak derivatives of functions in H¹₀(B, [symbol] ³). Parameter γ>0 controls the relative weighting of the derivative term. The derivative term produces a smoothing effect on the Hilbert space extension. γ is the contribution of the derivative (gradient) term in the inner product. d [symbol] _{Ω} is the shape gradient, which is a scalar function defined on the boundary ∂Ω. d [symbol] _{Ω} represents the local sensitivity of the objective function to changes at each point on the boundary. n_{∂Ω} is the outward normal on the boundary and specifies the direction perpendicular to the boundary at each point.

Optimization application 206 constructs the source term for the CHSE equation by evaluating the shape derivative of the objective function at the boundary of the shape/design domain. Optimization application 206 computes the shape gradient, d [symbol] Ω, which quantifies the sensitivity of the objective function to boundary variations. Optimization application 206 multiplies the shape gradient by the unit outward normal vector, n∂Ω, to capture the descent direction for the objective function. Optimization application 206 integrates the resulting product over the entire boundary to form a forcing function that encodes unsmoothed sensitivity data. Optimization application 206 reformulates the task of computing the CHSE velocity field as a variational minimization problem using Equation 7. The second term in Equation 7 represents the energetic cost imposed by the raw sensitivity information on the deformation field. Including the forcing function in the variational formulation drives the optimization in the descent direction indicated by the sensitivity data. Θ is the candidate velocity field, an element of the Sobolev space H¹₀(B, [symbol] ³). Θ represents the smooth deformation of the shape to be determined.

$$\begin{matrix}minimize & \frac{1}{2} {〈 〈 Θ , Θ 〉 〉}_{γ} - {\int }_{\partial Ω} d {𝒥}_{Ω} {n}_{\partial Ω} \cdot Θ \\ over & Θ ∈ {H}_{0}^{1} ( ℬ , {ℝ}^{3} ) .\end{matrix} \qquad ( 7 )$$

Optimization application 206 then sets up the HSE equation that will include the regularization framework to be used to produce a smooth and well-defined velocity field for updating the level-set function. Specifically, the left-hand side of Equation 6 and the first term in Equation 7, define the Hilbert space gradient via an inner product that incorporates both an L² term and a term involving the gradient of the velocity field. The construction of Equation 6 measures the “energy” or norm of the deformation field in the Sobolev space, providing a natural smoothing effect. Optimization application 206 establishes the inner product to ensure that the extended sensitivity information becomes tempered by a regularizing operator. The regularizing operator spreads the influence of localized changes across the design domain. The regularizing operator prevents oscillations and irregularities in the computed velocity field during later optimization steps. A solution to the HSE equation yields the unconstrained velocity field.

After choosing a finite element mesh (or similar discretization) within a narrow band around the boundary, optimization application 206 assembles a block-matrix system using Equation 8. Equation 8 describes a discrete version of the governing PDEs.

$$\begin{matrix}{K}^{( 00 )} {Θ}_{α} + {\sum }_{n} {K}^{( 0 n )} {V}_{α}^{( n )} {z}^{( n )} = {G}_{α}^{( 0 )} & for α = 1 , 2 , 3 \\ {\sum }_{α} {{[ {V}_{α}^{( n )} ]}^{⊤} [ {K}^{( 0 n )} ]}^{⊤} {Θ}_{α} + {\sum }_{α} {[ {V}_{α}^{( n )} ]}^{⊤} {K}^{( nn )} {V}_{α}^{( n )} {z}^{( n )} = {G}^{( n )} & for n = 1 , … , N .\end{matrix} \qquad ( 8 )$$

Θ_{α} are the unknown nodal values of the velocity field. K⁽⁰⁰⁾ is a matrix that contains the finite-element integrals over a reduced domain B′\∂B′. K⁽⁰⁰⁾ represents the “stiffness” or energy contributions from the interior nodes (those not on the boundary of B′) and is of size I×I, where I is the number of nodes in that region. K⁽⁰ⁿ⁾ couples nodes in the interior region B′\ aB' with nodes on the boundary of the interface region, ∂N_{I}⁽ⁿ⁾. K⁽⁰ⁿ⁾ is of size I×I₍ₙ₎. where I₍ₙ₎ is the number of nodes on ∂N_{I}⁽ⁿ⁾.

For each interface n and direction a, V_{α}⁽⁰⁾ is the matrix of nodal values for the allowed motion fields on ∂N_{I}⁽ⁿ⁾. V_{α}⁽⁰⁾ has dimensions I(n)×dₙ, where dₙ is the number of degrees of freedom (or allowed motion modes) for that interface. z⁽ⁿ⁾ is a vector of coefficients (of size dₙ) associated with the allowed motion basis for interface n. z⁽ⁿ⁾ scales the allowed motion fields represented by V_{α}⁽⁰⁾ in the finite element representation. G_{α}⁽⁰⁾ is a vector that collects the source term contributions derived from the boundary integral (involving d [symbol] Ω and n∂Ω) for nodes in B′\∂B′, for each Cartesian component α. G_{α}⁽⁰⁾ is of length I.

For each interface n, G⁽ⁿ⁾ (of size dₙ) represents the source term contributions on the boundary of the interface region, obtained by integrating the product of the shape sensitivity and the allowed motion fields over ∂N_{I}⁽ⁿ⁾. The block-matrix system is positive definite and can be efficiently solved using standard linear solvers. The block matrix system provides the discrete approximation of the HSE equation and yields the extension velocity field that will drive the shape optimization update. Optimization application 206 uses Equations 6, 7, and 8 to ensure that the extension velocity field is computed in a manner that both optimizes the objective function [symbol] and adheres to the smoothness and constraint requirements for the shape.

Optimization application 206 restricts the velocity field in the interface region to a finite-dimensional subspace of allowed infinitesimal motions. Optimization application 206 determines a finite-dimensional space for allowed infinitesimal motions near an interface according to Equation 9. Equation 9 defines a basis that spans the space of infinitesimal translation, rotation, and orthotropic scaling vector fields permitted by the constraints on the interface and that is aligned with the interface orientation and location.

$$\begin{matrix}{Θ}_{ε = 0} ( x ) = {\sum }_{s = 1}^{{d}_{n}} {z}_{s}^{( n )} {V}_{s}^{( n )} ( x ) & ∀ x ∈ {I}_{( n )}^{}\end{matrix} \qquad ( 9 )$$

In Equation 9, Θ_{ε=0}(x) denotes the velocity field at time ε=0. Vₛ⁽ⁿ⁾ denotes the s-th basis vector field for the allowed infinitesimal motions near interface Γ_{I}⁽ⁿ⁾. The scalar coefficient zₛ⁽ⁿ⁾ corresponds to the weight for basis vector Vₛ⁽ⁿ⁾. The summation index s runs from 1 to dₙ, where dₙ represents the number of degrees of freedom allowed by the motion constraints. The variable x denotes an arbitrary point within the tubular neighborhood N_{I}⁽ⁿ⁾. The subscript n indexes a specific interface when multiple interfaces exist.

Optimization application 206 expresses the velocity in the interface neighborhood as a linear combination of the basis vector fields with scalar coefficients. Optimization application 206 then imposes allowed motion constraints on the solution space by restricting the velocity to match the linear combination of Equation 10.

Optimization application 206 ensures that the computed velocity field adheres to the permitted motion modes for grid points within the tubular region around the interface. Grid points are the nodes of the finite element mesh on the background grid. Optimization application 206 integrates the allowed motion constraints with the Hilbert space extension method to produce a descent direction that preserves interface geometry and maintains smoothing properties in subsequent level set updates.

Equation 9 expresses the velocity field at time ε=0 as a linear combination of basis vector fields that span the finite-dimensional space of allowed infinitesimal motions. Equation 10 introduces a constraint in the variational problem that forces the velocity field to match the linear combination specified by Equation 19 for every point x in the tubular neighborhood N_{I}⁽ⁿ⁾ of each interface. Optimization application 206 uses Equation 10 to restrict the solution space of the velocity to the allowed motions. Optimization application 206 ensures that the computed velocity conforms to the prescribed motion modes for grid points within the tubular neighborhood. The allowed motion constraints integrate with the Hilbert space extension method to yield a descent direction that preserves interface geometry and maintains smoothing properties during subsequent level set updates.

$$\begin{matrix}minimize & \frac{1}{2} {〈 〈 Θ , Θ 〉 〉}_{γ} - {\int }_{\partial Ω} d {𝒥}_{Ω} {n}_{\partial Ω} \cdot Θ \\ subject to & \begin{matrix}Θ ( x ) = {\sum }_{s = 1}^{{d}_{n}} {z}_{s}^{( n )} {V}_{s}^{( n )} ( x ) & ∀ x ∈ {I}_{( n )}^{} and ∀ n = 1 , … , N\end{matrix} \\ over & Θ ∈ {H}_{0}^{1} ( ℬ , {ℝ}^{3} ) and {z}_{1}^{( 1 )} , … , {z}_{{d}_{N}}^{( N )} ∈ ℝ .\end{matrix} \qquad ( 10 )$$

Optimization application 206 restricts the velocity field for each tubular neighborhood to lie in the finite-dimensional subspace spanned by the allowed infinitesimal motion basis vectors via Equation 10. For every interface segment indexed by n and for every point x in the tubular neighborhood N_{I}⁽ⁿ⁾, the velocity field (x) is a linear combination of basis vectors V₁⁽ⁿ⁾, V₂⁽ⁿ⁾. . . , V_{d}_{ₙ}⁽ⁿ⁾, with corresponding scalar coefficients z₁⁽ⁿ⁾, z₂⁽ⁿ⁾. . . , z_{d}_{ₙ}⁽ⁿ⁾. Optimization application 206 restricts the feasible solution space so that only deformations corresponding to permitted motions occur in the vicinity of the interface via Equation 10. This constraint effectively selects or “carves out” a subset of all possible velocity fields, ensuring that the computed velocity adheres strictly to the constrained motions during the level set update process.

As discussed, Equation 7 establishes an HSE residual that minimizes an energy term and aligns the velocity field with sensitivity information. The constraint imposed by Equation 10 couples with the minimization framework from Equation 7. The coupling restricts the feasible deformation space so that the computed velocity not only drives performance improvement but also adheres strictly to the allowed motions near each interface.

Optimization application 206 then computes the constrained Hilbert space extension velocity field according to Equation 11. Optimization application 206 reformulates the variational problem over the reduced domain B′ by excluding the interiors of the interface neighborhoods. The reduced domain B′ excludes the interiors of the interface neighborhoods to focus on the region where allowed motion constraints matter, enforced by constraint terms applied by optimization application 206.

To constrain the velocity field, optimization application 206 defines a CHSE residual by adding penalty terms, such as a Nitsche term, to the HSE residual. The CHSE residual incorporates both the energy term and the sensitivity term. The energy term represents the Hilbert inner product of the velocity field with itself over B′, which measures the smoothness and energy cost of the deformation. The sensitivity term integrates boundary sensitivity data to capture the descent direction for the objective function [symbol] .

Optimization application 206 sets the variation of the CHSE residual to zero with respect to variations in the velocity field Θ and the scalar coefficients z using Equation 11. Equation 11 couples the velocity field and the z-coefficients, ensuring that the computed velocity aligns with the descent direction indicated by the sensitivity analysis and satisfies the allowed motion constraints imposed on the interface neighborhoods.

$$0 = {\int }_{{ℬ}^{′}} Θ \cdot δΘ + {γ}^{2} {\int }_{{ℬ}^{′}} D Θ : D δΘ + {\sum }_{n = 1}^{N} {\sum }_{s , t = 1}^{{d}_{n}} δ {z}_{s}^{( n )} {z}_{t}^{( n )} ( {V}_{s}^{( n )} \cdot {V}_{t}^{( n )} + {γ}^{2} {DV}_{s}^{( n )} : {DV}_{t}^{( n )} ) - \frac{\partial δΘ}{\partial n} \cdot ( Θ - {\sum }_{s = 1}^{{d}_{n}} {z}_{s}^{( n )} {V}_{s}^{( n )} ) - \frac{\partial Θ}{\partial n} \cdot ( δΘ - {\sum }_{s = 1}^{{d}_{n}} δ {z}_{s}^{( n )} {V}_{s}^{( n )} ) - {\int }_{\partial Ω ⋂ {ℬ}^{′}} d {𝒥}_{Ω} {n}_{\partial Ω} \cdot δΘ - {\sum }_{n = 1}^{N} {\sum }_{s , t = 1}^{{d}_{n}} δ {z}_{s}^{( n )} d {𝒥}_{Ω} {n}_{\partial Ω} \cdot {V}_{s}^{( n )} . \qquad ( 11 )$$

Θ denotes the constrained Hilbert space velocity field defined on B′. In this formulation, the penalty terms, which serve as constraint terms in this context ensure that Θ satisfies the allowed motion restrictions. δΘ denotes an arbitrary variation of the velocity field Θ within the space H₀¹(B′, [symbol] ³). DΘ denotes the gradient (or first derivative) of the velocity field Θ, while DoO denotes the gradient of the variation δΘ. The colon operator (:) represents the Frobenius inner product between matrices (e.g., a tensor contraction). The summation Σₙ₋₁^{N} denotes a summation over all interface segments indexed by n. Σ_{s,t=1}^{(d}^{ₙ}⁾ denotes a double summation over the degrees of freedom for the allowed motions at interface n, where dₙ is the number of allowed degrees of freedom. δzₛ⁽ⁿ⁾ denotes the variation of the scalar coefficient associated with the s-th basis vector for interface n. zₜ⁽ⁿ⁾ denotes the scalar coefficient corresponding to the t-th basis vector for interface n. Vₛ⁽ⁿ⁾ denotes the s-th allowed infinitesimal motion basis vector for interface n, and Vₜ⁽ⁿ⁾ denotes the t-th basis vector for interface n. ∂N_{I}⁽ⁿ⁾ denotes the boundary of the tubular neighborhood N_{I}⁽ⁿ⁾ for interface n. ∂δΘ/∂n denotes the normal derivative of the variation δΘ on the boundary ∂N_{I}⁽ⁿ⁾. ∂Θ.∂n denotes the normal derivative of the velocity field Θ on the boundary ∂N_{I}⁽ⁿ⁾. (Θ−Σₛ₌₁^{d}^{ₙ} zₛ⁽ⁿ⁾ Vₛ⁽ⁿ⁾ denotes the difference between the velocity field Θ and the prescribed representation of the extension velocity field Θ as a linear combination of allowed motion basis vectors on aN_{I}⁽ⁿ⁾. d [symbol] _{Ω} denotes the shape gradient of the objective function [symbol] with respect to the shape Ω. n_{∂Ω} denotes the outward normal vector on the boundary ∂Ω of the shape Ω. The constraint terms appear in the equation as the boundary integrals over each ∂N_{I}⁽ⁿ⁾ that penalize deviations of the velocity field from its prescribed representation, restricting the solution space such that the solution space conforms to the affine motions.

Optimization application 206 solves the constrained Hilbert space extension equations, which derive from the augmented variational formulation of Equations 7 and 10. In solving the constrained Hilbert space extension equations, optimization application 206 computes an extension velocity field that drives the update to the level-set function.

Optimization application 206 solves the constrained Hilbert space extension equation using standard numerical methods, (e.g. the finite element method, conjugate gradient methods or direct solvers, and/or the like). The numerical solution yields a smooth velocity field that satisfies the energy minimization criteria and the imposed interface constraints. Once optimization application 206 obtains the solution over the reduced domain, optimization application 206 extends the computed velocity field into the interface neighborhoods using the computed coefficients. The computed coefficients, denoted as z, weigh the allowed-motion basis functions that appear in Equation 10 and in the weak form in Equation 11.

Optimization application 206 then constructs the updated velocity field that drives the update to the level-set function. The resulting velocity field is explicitly both space-and time-dependent, ensuring that near each interface the deformation conforms to the allowed motions while being compatible with the free-form shape changes elsewhere. Optimization application 206 determines the velocity field, Θ, using Equation 12.

$${Θ}_{ε} := {Θ}_{CHSE} + {\sum }_{n = 1}^{N} {χ}_{I}^{( n )} ( {Θ}_{ε}^{allowed , ( n )} - {Θ}_{CHSE} ) \qquad ( 12 )$$

Θ_{CHSE} represents the constrained Hilbert space extension velocity field computed in earlier steps. For each interface n, term Θ_{ϵ}^{allowed,(n)} denotes the infinitesimal generator of the desired compound motion. Optimization application 206 constructs Θ_{ϵ}^{allowed,(n)} using the translation, rotation, and scaling parameters (denoted t_{I}⁽ⁿ⁾, h_{I}⁽ⁿ⁾, and d_{I}⁽ⁿ⁾, respectively), derived from corresponding coefficients, denoted as z, computed from the allowed motion constraints in the variational formulation. The dependence on E reflects the time-dependence of the compound motion.

Equation 12 defines a smooth, positive cutoff function χ_{I}⁽ⁿ⁾ on the domain B. The definition customizes the function for each interface n. The function equals one in the neighborhood N_{I}⁽ⁿ where allowed motion fully applies and gradually decreases to zero beyond a slightly larger tubular neighborhood of the interface. χ_{I}⁽ⁿ⁾ localizes the adjustment to the velocity field so that optimization application 206 can impose the allowed macroscopic motion in the vicinity of each interface while leaving Θ_{CHSE} unaltered in other regions. Equation 12 ensures that the velocity field Oe transitions smoothly between the unconstrained velocity field Θ_{CHSE} and the allowed motion Θ_{ϵ}^{allowed,(n)} in the region where the cutoff function χ_{I}⁽ⁿ⁾ exerts influence. At ϵ=0 the unconstrained velocity field equals the allowed velocity field in the region where the cutoff function χ_{I}⁽ⁿ⁾ remains active (e.g. Θ_{ϵ}^{allowed,(n)}=Θ_{CHSE}). The equality guarantees continuity of the velocity field at the initial time.

The velocity field updates as optimization application 206 incorporates the time dependence through the parameter Θ_{ϵ}^{allowed,(n)}. Incorporating Θ_{ϵ}^{allowed,(n)} produces a continuous updating of the level-set function. As a result, the interface undergoes the desired compound motion for small e while the global shape update remains consistent with the unconstrained sensitivity-driven update outside the interface regions.

Using Equation 12, optimization application 206 completes the construction of the velocity field by combining the baseline extension velocity with localized corrections that impose the allowed motions. This guarantees that the solution of the transport equation. Using the time-dependent Θ_{ϵ}, optimization application 206 produces a continuous update of the level-set function that respects the optimization objectives and the interface-specific constraints.

Optimization application 206 constructs the velocity field so that the interfaces undergo allowed motions that are consistent with the infinitesimal generators of. Equations 13 and 14.

$${Θ}_{ε}^{allowed} ( x ) := t + ( h ) ( x - p - ε t ) + exp ( ε ( h ) ) D {⊤}^{} exp ( - ε ( h ) ) ( x - p - ε t ) \qquad ( 13 )$$

Translation component t represents a uniform translation of the interface. When optimization application 206 imposes an orientation by an orthogonal matrix Q, the optimization application 206 can express the translation vector as t=Q*t₀ for some t₀∈R³, ensuring that the translation occurs in a prescribed direction.

In the rotational component (A(h)(x−p−ϵt)) the term A(h) is an antisymmetric matrix that generates rotations about a fixed point p∈R³. Optimization application 206 defines the rotational component so that A(h)x=h×x where h is the rotation axis. The factor (x−p−ϵt) adjusts the position of x relative to the fixed point p, accounting for the translation scaled by ϵ. This introduces a time dependence into the rotation.

In the context of the scaling component, (exp(ϵA(h))QDQ^{T}exp(−ϵA(h))(x−p−ϵt)), D is a diagonal matrix D=diag(d) that contains the orthotropic scaling factors, and Q aligns the scaling with the interface's orientation. Matrix exponentials ensure that application 206 applies the scaling optimization smoothly over time while being appropriately transformed by the rotation. This scaling term modifies the size and proportions of the interface without altering the fundamental geometry of the interface. Equation 13 defines an affine vector field that governs the allowed compound motion. The dependence on ϵ ensures that the motion is time-dependent, enabling the interface to update smoothly under successive, small deformations.

Optimization application 206 can alternatively use a simplified form of the allowed infinitesimal generator at the initial time (ϵ=0) based on Equation 14.

$${Θ}_{ε = 0}^{allowed} ( x ) := t + ( h ) ( x - p ) + D {⊤}^{} ( x - p ) \qquad ( 14 )$$

Using Equation 14, optimization application 206 retains translation (t) directly. Optimization application 206 additionally applies rotation A(h)(x−p) without the time-dependent correction, representing the instantaneous rotational effect about the fixed point p. Optimization application 206 also applies scaling (Q D Q_{T}(x−p)) in the instantaneous form.

Equation 14 shows that, at ϵ=0, the allowed motion is the sum of the infinitesimal generators of translation, rotation, and scaling. This composite vector field forms a basis for a finite-dimensional space of allowed motions.

Optimization application 206 constrains the velocity field to lie in the subspace defined by Equations 13 and 14. Optimization application 206 aligns the velocity field with the allowed macroscopic motions such that the translations shift the interface, rotations reorient it, and scaling adjusts the size. The explicit time dependence in Equation 13 allows for a continuous update, while the instantaneous form in Equation 14 confirms that the constraints are met at the onset of the deformation.

Once the velocity field has been constructed, optimization application 206 solves the transport equation. The transport equation in level-set methods is typically a Hamilton-Jacobi type partial differential equation (PDE). The role of the transport equation is to propagate the level-set function in time, updating the interface of the shape according to the prescribed velocity field.

The optimization application 206 updates the level-set function that defines the shape boundary by solving the Hamilton-Jacobi transport equation of Equation 15.

$$\begin{matrix}\frac{\partial {F}_{ε}}{\partial ε} + 〈 ▽ {F}_{ε} , {Θ}_{ε} 〉 = 0 \\ {F}_{0} = F\end{matrix} \qquad ( 15 )$$

Optimization application 206 integrates the transport equation over a short time interval using an updated velocity field to yield a one-parameter family of level-set functions, Fₑ. The one-parameter family denotes a continuous collection of level-set functions, each corresponding to a different value of the small scalar parameter ε, and defining a continuum of perturbed shapes. In the final step, optimization application 206 solves the transport equation with this updated velocity field to propagate the level-set function. In the solution to the transport equation, optimization application 206 ensures that the constrained interfaces move in accordance with the allowed motions while the remainder of the boundary updates in a freeform way. Optimization application 206 iteratively recalculates the level-set function while maintaining the constraints throughout the optimization process until optimization application 206 reaches convergence.

Optimization application 206 iteratively repeats the optimization steps until the shape converges to an optimized shape. Optimization application 206 can determine whether the shape has converged to the optimized shape using any technically feasible convergence test. In some embodiments, optimization application 206 determines that the shape has converged when the relative change in the objective function [symbol] over two or more consecutive iterations falls below a predefined threshold. In some embodiments, optimization application 206 determines that the shape has converged when an L₂-norm of the difference between the level-set function of two successive iterations is less than a specified tolerance. In some embodiments, optimization application 206 checks the magnitude of the velocity field. When optimization application 206 determines that the velocity field is below a velocity threshold, optimization application 206 determines that the shape has converged. When the shape has not converged, optimization application 206 performs another iteration of the optimization steps. When the shape has converged, optimization application 206 saves the shape generated by the latest iteration as an optimized shape 212.

### Example Assembly

FIG. 3 illustrates an example multi-component assembly 300, according to various embodiments. As shown, multi-component assembly 300 includes, without limitation, a component 302 to be optimized, having interfaces 304, and coupled to additional assembly components, such as component 306.

Component 302 can be optimized by optimization application 206. In various embodiments, optimization application 206 optimizes component 302 to improve a strength-to-weight ratio of component 302 while adhering to design constraints at interfaces 304. During optimization, any modifications in the shape of component 302 preserve connectivity with adjoining components, such as component 306, without altering the functional characteristics of interfaces 304.

Interfaces 304 define the mechanical couplings between component 302 and the additional components of assembly 300. In accordance with engineering requirements, interfaces 304 can be implemented as welded connections or joint connections that permit specific relative motions between components. The geometry of interfaces 304 should thus be constrained to ensure both the functional and structural integrity of component 302 and assembly 300.

Component 306 is configured to interconnect with component 302 via one of the interfaces 304. In various embodiments, the design of component 302 is optimized while preserving the size, location, or rotation of interfaces 304, as specified by the designer. Otherwise free form shape modification to the shape of component 302 is permitted, provided that interfaces 304 retain desired functionality.

As shown in FIG. 3, a first interface 304 of component 302 couples component 302 to component 302. First interface 304 is a rotational coupling between component 302 and component 302. In order for first interface 304 to allow relative rotation of component 302 to component 302, first interface 304 is subject to affine constraints that allow first interface 304 to be translated (e.g. moved within the plane parallel to a face of component 302) or scaled in size. In addition to the constraints on interfaces 304, other non-interface areas of component 302 can be moved, resized, and/or removed to reduce a weight of component 302.

### Advantages of Optimization using Constraints

FIG. 4 is an example of a comparison 400 of optimization methods, according to various embodiments. As shown, comparison 400 includes, without limitation, components 402A, 402B and optimized components 410A, 410B. Component 402A includes, without limitation, circular interface 406A and fixed interfaces 408A, 408B. Component 402B includes, without limitation, circular interface 406B and fixed interfaces 408C, 408D. Also shown in FIG. 4 is an example velocity field 404A for updating component 402A using a conventional optimization method and an example velocity field 404B for updating component 402B using optimization application 206. Optimized component 410A includes, without limitation, a noncircular interface 412A. Optimized component 410B includes, without limitation, a circular interface 412B.

Component 402A is an L-bracket having fixed interfaces 408A, 408B used to mount component 402A to other components (not shown). Component 402A further includes circular interface 406A used to allow a second component (not shown) to rotate relative to component 402A. During optimization, fixed interfaces 408A, 408B are not allowed to translate, rotate, or change in size. In contrast, circular interface 406A is allowed to be adjusted.

During optimization using a conventional optimization method, the conventional optimization method evaluates a shape of component 402A and generates velocity field 404A. Using velocity field 404A and additional velocity fields over multiple optimization iterations, the conventional optimization method updates component 402A to component 410A. As a result, a shape and location of circular interface 406A is updated to interface 412A, However, because the conventional optimization method does not apply constraints to circular interface 406A, interface 412A is not circular and is no longer usable to allow the second component to rotate relative to component 402A.

During optimization, optimization application 206 evaluates a shape of component 402B and generates velocity field 404B. Using velocity field 404B and additional velocity fields over multiple optimization iterations, optimization application 206 updates component 402B to component 410B. As a result, a shape and location of circular interface 406A is updated to circular interface 412B, However, because optimization application 206 has applied constraints to circular interface 406B, circular interface 412B retains the same circular shape as circular interface 406B and still allows the second component to rotate relative to component 402B at circular interface 406B. Notably, optimization application 206 overcomes the limitations of the conventional optimization method, because optimization application 206 retains the functionality of circular interface 406B to produce circular interface 412B, whereas the conventional optimization method does not.

### Optimization using Constraints

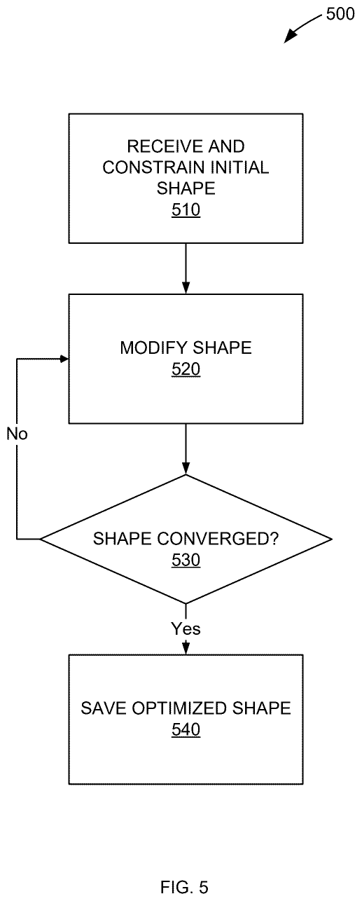

FIG. 5 sets forth a flow diagram of method steps for optimizing a shape of a component, according to various embodiments. Although the method steps are described in conjunction with the embodiments of FIGS. 1-4, persons of ordinary skill in the art will understand that any system configured to perform the method steps, is within the scope of the invention

As shown, a method 500 begins at a step 510, where optimization application 206 receives and constrains initial shape 210. Optimization application 206 represents the shape with a level-set function. Optimization application 206 identifies interface regions for component interaction in an assembly. Optimization application 206 partitions the overall boundary into multiple subsets that correspond to interfaces. Optimization application 206 assigns each interface a spatial location parameter and an orientation and defines the allowed affine motions for interfaces and restricts deformations to a finite-dimensional subspace using Equation 1. Using the constraints of Equation 1, allows optimization application 206 to preserve the interface geometry during optimization. Optimization application 206 then performs iterative optimization on initial shape 210 beginning with step 520 where initial shape 210 is used as the shape to optimize.

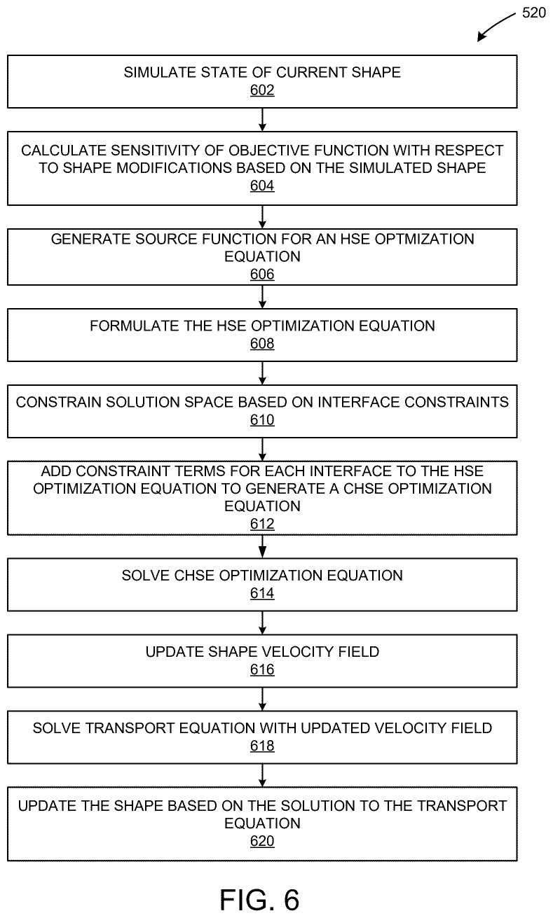

At a step 520, optimization application 206 modifies the shape. Optimization application 206 first simulates the state of the current shape based on an elastic response and strain when the shape is under a load. Optimization application 206 then uses the simulation results to calculate sensitivities of the objective function [symbol] with respect to the shape modifications. Optimization application 206 then uses the sensitivity information to construct the source terms for a CHSE equation. Optimization application 206 then solves the CHSE equation by constraining the solution space for allowed affine motions. Optimization application 206 uses the solution to the CHSE equation to construct an updated velocity field. Optimization application 206 applies the velocity field to a transport equation, which optimization application 206 solves and uses the solution to update the level-set function and, ultimately, the shape. Step 520 is described in further detail in FIG. 6.

At a step 530, optimization application 206 checks for shape convergence. In some embodiments, optimization application 206 determines that the shape has converged when the relative change in the objective function after two or more consecutive iterations falls below a predefined threshold. In some embodiments, optimization application 206 determines that the shape has converged when an L₂-norm of the difference between the level-set function of two successive iterations is less than a specified tolerance. In some embodiments, optimization application 206 checks the magnitude of the velocity field. When optimization application 206 determines that the velocity field is below a velocity threshold, optimization application 206 determines that the shape has converged. When the shape has not converged, optimization application 206 performs another optimization iteration by returning to step 520. When the shape has converged, optimization application 206 save the shape using step 540.

At a step 540, optimization application 206 saves the optimized shape. Optimization application 206 saves the optimized shape as optimized shape 212 to storage 208. For example, optimization application 206 can save optimized shape 212 as a level-set function. Optimized shape 212 retains the defined interface constraints and functional characteristics, ensuring functionality within the overall assembly.

FIG. 6 sets forth a flow diagram of method steps for modifying a shape of a component, according to various embodiments. Although the method steps are described in conjunction with the embodiments of FIGS. 1-4, persons of ordinary skill in the art will understand that any system configured to perform the method steps, is within the scope of the invention

As shown, step 520 begins at a step 602, where optimization application 206 simulates the state of the current shape. In the example of compliance minimization, simulating the state of the current shape involves simulating the structural response (e.g. stresses, displacements, etc.) of the current shape. Simulating the structural response supports evaluation of the objective function for the shape. Optimization application 206 uses a chosen shape function and computes the elastic response and the resulting strain to capture the state of the shape under load. Optimization application 206 computes the elastic response and corresponding strain by solving the governing partial differential equations that enforce mechanical equilibrium and apply specified boundary conditions using Equation 2.

At a step 604, optimization application 206 calculates the sensitivity of the objective function with respect to shape modifications based on the simulated state. Optimization application 206 determines the sensitivity of the objective function to shape changes with Equation 3, which expresses the general form of the shape derivative via the shape gradient. Optimization application 206 considers the normal component of the infinitesimal deformation to capture the directional influence on performance. For the case of compliance minimization, optimization application 206 determines the shape gradient using Equation 4, which quantifies the sensitivity at each boundary point on the shapeln the example of compliance minimization, optimization objective 206 calculates the sensitivity of elastic compliance using Equation 5. Equation 5 decomposes contributions from fixed, loaded, and free boundary segments and defines the rate at which compliance changes with an infinitesimal deformation. Optimization application 206 incorporates the effects of load distributions, body forces, and geometric factors such as mean curvature to calculate the sensitivity of the shape under applied loads using Equation 5.

At a step 606, optimization application 206 generates the source function for an HSE optimization equation. Optimization application 206 determines a relationship between the shape derivative and the Hilbert space gradient by choosing an appropriate inner product and extending the boundary sensitivities through the HSE method. Optimization application 206 uses Equation 6 to generate a smooth and physically plausible velocity field that serves as a descent direction for the shape optimization process used to update the shape. Optimization application 206 then constructs the forcing function by multiplying the shape gradient by the unit outward normal vector and integrating the product over the entire boundary, using Equation 7.

At a step 608, optimization application 206 formulates the HSE optimization equation. Optimization application 206 determines an inner product that combines L² terms with gradient terms to measure the energy of the deformation field using Equation 5. Optimization application 206 defines an energy term in Equation 7 that regularizes boundary sensitivity information and yields a smooth candidate velocity field. Optimization application 206 discretizes the governing PDEs over a narrow band around the boundary using finite element methods according to Equation 8. Optimization application 206 assembles a block-matrix system that includes stiffness matrices and coupling terms, as well as allowed-motion basis matrices and corresponding coefficient vectors using Equation 8.

At a step 610, optimization application 206 constrains the solution space based on interface constraints. Optimization application 206 constrains the velocity field in the vicinity of each interface to a finite-dimensional subspace of allowed motions. Optimization application 206 defines a basis that spans the space of permitted affine motion constraints for each interface according to Equation 9. Optimization application 206 then enforces these allowed motion constraints by requiring that the velocity field match the prescribed linear combination across the entire tubular neighborhood, using Equation 10.

At step 612, optimization application 206 adds constraint terms for each interface to the CHSE optimization equation. Optimization application 206 reformulates the variational problem (e.g., the functional minimization framework with combined energy and sensitivity terms, augmented by allowed motion constraints) over a reduced domain by excluding the interiors of the interface neighborhoods, focusing on regions where allowed motion constraints apply. Optimization application 206 defines a CHSE residual by adding penalty terms, e.g. via a Nitsche method, to incorporate an energy term that measures the smoothness of the velocity field and a sensitivity term that captures the descent direction. Optimization application 206 then sets the variation of the CHSE residual to zero with respect to variations in the velocity field Θ and the scalar coefficients z using Equation 11.

At a step 614, Optimization application 206 solves the CHSE optimization equation. Optimization application 206 uses the block-matrix system determined during step 608 to generate a velocity field that modifies the level-set update. Optimization application 206 solves the block-matrix system using standard numerical methods (e.g. conjugate gradient methods, or direct solvers) and then extends the computed velocity field into the interface neighborhoods using computed coefficients, denoted as z, which weigh the allowed-motion basis functions.

At a step 616, Optimization application 206 updates the shape velocity field. Optimization application 206 constructs an updated velocity field that is both space-and time-dependent using the unconstrained velocity field with localized corrections imposed by a smooth cutoff function using Equation 12. Optimization application 206 further refines the update by incorporating the allowed affine motions. Optimization application 206 then defines an affine vector field that captures the compound motion using Equation 13. In addition, optimization application 206 provides an instantaneous representation of the allowed motions at the initial time, forming a basis for the finite-dimensional subspace of permitted deformations using Equation 14. Optimization application 206 restricts the velocity field to lie within the allowed motion subspace using Equations 13 and 14 together.

At a step 618, optimization application 206 solves the transport equation. Optimization application 206 propagates the level-set function in time by integrating the Hamilton-Jacobi partial differential equation of Equation 15 using the updated velocity field.

At step 620, optimization application 206 updates the shape based on the solution to the transport equation. Specifically, optimization application 206 updates the level-set function which represents the shape, using the solution of the transport equation.

### Effects of Different Interface Constraints

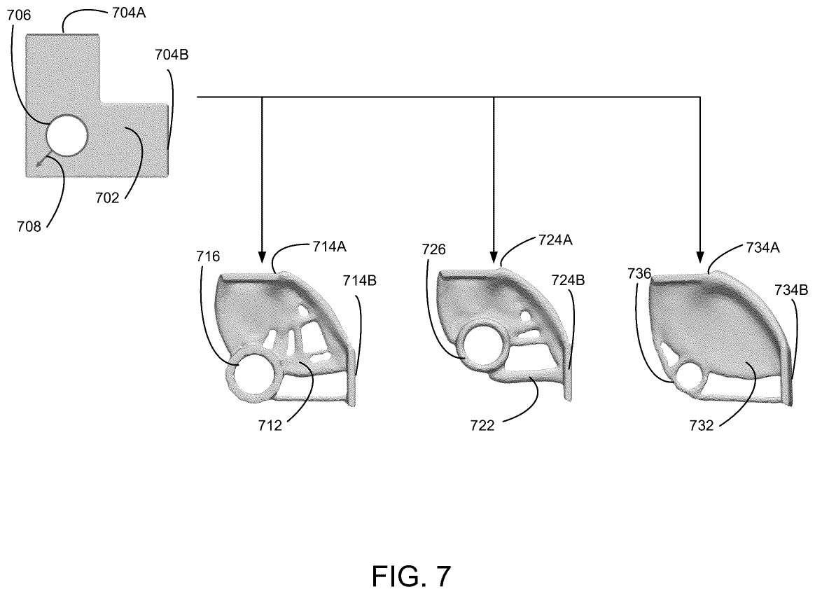

FIG. 7 illustrates examples of shape optimization using different interface constraints, according to various embodiments. As shown, FIG. 7 includes, without limitation, a component 702 and optimized components 712, 722, 732. Component 702 includes, without limitation, a circular interface 706, and fixed interfaces 704A, 704B. Optimized component 712 includes, without limitation, a circular interface 716, and fixed interfaces 714A, 714B. Optimized component 722 includes, without limitation, a circular interface 726, and fixed interfaces 724A, 724B. Optimized component 732 includes, without limitation, a circular interface 736, and fixed interfaces 734A, 734B. Also shown is an arrow 708, which indicates an example of a direction of a force applied to interface 706 by a second component (not shown).

Component 702 is an L-bracket having fixed interfaces 704A and 704B used to mount component 702 to other components (not shown). Component 702 further includes circular interface 706 used to allow the second component to rotate relative to component 702.

In one embodiment, optimization application 206 generates optimized component 712 from component 702 with strength-to-weight ratio as the objective function. Optimized component 712 is an optimized version of component 702 where both the fixed interfaces 704A and 704B and circular interface 706 are constrained so that fixed interfaces 704A and 704B and circular interface 706 are not allowed to translate, rotate or scale. As a result, in optimized component 712, fixed interface 714A has a same position, orientation, and size as fixed interface 704A and fixed interface 714B has a same position, orientation, and size as fixed interface 704B. Importantly, circular interface 716 has a same position, orientation, and size as circular interface 706.

In one embodiment, optimization application 206 generates optimized component 722 from component 702 with strength-to-weight ratio as the objective function. Optimized component 722 is an optimized version of component 702 where the fixed interfaces 704A and 704B are constrained so that fixed interfaces 704A and 704B are not allowed to translate, rotate or scale. Furthermore, circular interface 706 is constrained so that circular interface 706 is allowed to translate but not to rotate or scale. As a result, in optimized component 722, fixed interface 724A has a same position, orientation, and size as fixed interface 704A. Fixed interface 724B has a same position, orientation, and size as fixed interface 704B. Importantly, circular interface 726 has an optimized position within optimized component 722 while retaining the same size and orientation as circular interface 706

In one embodiment, optimization application 206 generates optimized component 732 from component 702 with strength-to-weight ratio as the objective function. Optimized component 732 is an optimized version of component 702 where the fixed interfaces 704A and 704B are constrained so that fixed interfaces 704A and 704B are not allowed to translate, rotate or scale. Furthermore, circular interface 706 is constrained so that circular interface 706 is allowed to scale but not to rotate or translate. As a result, in optimized component 732, fixed interface 734A has a same position, orientation, and size as fixed interface 704A. Fixed interface 734B has a same position, orientation, and size as fixed interface 704B. Importantly, circular interface 736 has an optimized scale within optimized component 732 while retaining the same orientation and position as circular interface 706.

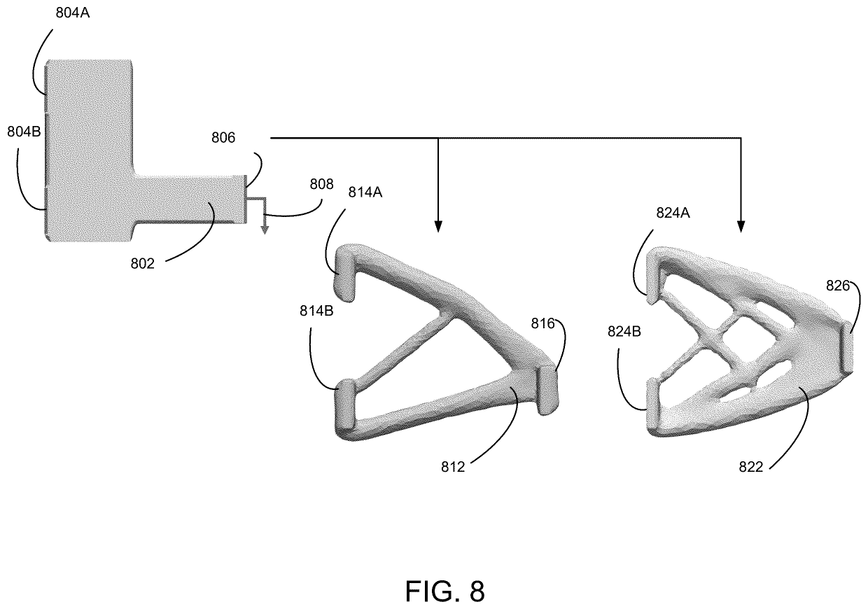

FIG. 8 examples of shape optimization using different interface constraints, according to various embodiments. As shown, FIG. 8 includes, without limitation, component 802, optimized component 812, and an optimized component 822. Component 802 includes, without limitation, an interface 806, and fixed interfaces 804A, 804B. Optimized component 812 includes, without limitation, an interface 816, and fixed interfaces 814A, 814B. Optimized component 822 includes, without limitation, interface 826, and fixed interfaces 824A, 824B. Also shown is an arrow 808, which indicates an example of a direction of a force applied to interface 806 by a second component (not shown). Component 802 is a cantilever beam having fixed interfaces 804A and 804B, and interface 806. Component 802 is used to mount component 802 to other components (not shown). Component 802 further includes interface 806 used to allow a second component (not shown) to affix to component 802.

In one embodiment, optimization application 206 generates optimized component 812 from component 802 with strength-to-weight ratio as the objective function. Optimized component 812 is an optimized version of component 802 where both the fixed interfaces 804A and 804B and interface 806 are constrained so that fixed interfaces 804A and 804B and interface 806 are not allowed to translate, rotate or scale. As a result, in optimized component 812, fixed interface 814A has a same position, orientation, and size as fixed interface 804A and fixed interface 814B has a same position, orientation, and size as fixed interface 804B. Importantly, interface 816 also has a same position, orientation, and size as interface 806.

In one embodiment, optimization application 206 generates optimized component 822 from component 802 with strength-to-weight ratio as the objective function. Optimized component 822 is an optimized version of component 802 where both the fixed interfaces 804A and 804B are constrained so that fixed interfaces 804A and 804B and interface 806 are not allowed to rotate or scale but may translate freely. As a result, in optimized component 822, fixed interface 824A has a same position, orientation, and size as fixed interface 804A and fixed interface 814B has a same position, orientation, and size as fixed interface 804B. Importantly, interface 826 has an optimized position within optimized component 822 while retaining the same size and orientation as interface 806.

In sum, the disclosed embodiments introduce techniques for level set-based shape optimization for a component along specified interface portions according to affine constraints with conventional free-form updates applied to other portions of the component. In particular, the techniques include receiving an initial shape for a component that includes interfaces between the component and one or more other components and the constraints associated with the interfaces. Within an iterative optimization loop, a multi-step optimization occurs. A first step simulates the state of the current shape of the component. A second step calculates the sensitivity of an objective function with respect to the modifications made to the shape. A third step generates a source function for the CHSE optimization equation. A fourth step constrains the solution space based on interface constraints, ensuring that the shape remains compatible with adjoining components in the assembly. A fifth step adds the constraint terms to the CHSE optimization equation for each of the interfaces. A sixth step solves the CHSE optimization equation, which yields an updated velocity field for the shape at the current iteration. A seventh step solves a transport function using the updated velocity field. An eighth step updates the shape based on the solution to the transport equation. A ninth step checks to see whether the shape has converged. Finally, once convergence of the shape is detected, a final step saves the final shape.

One technical advantage of the disclosed techniques relative to the prior art is that the disclosed techniques enable free-form optimization of non-interface regions of a component while allowing interface regions of the component to be modified in a manner that does not affect the functionality of the interface. These techniques allow more portions of a component (e.g., the interfaces) to be modified during optimization. As a result, the disclosed techniques result in components having a higher level of optimization than components optimized using conventional techniques. The higher level of optimization results in components that are cheaper and lighter than components optimized using conventional techniques. Moreover, the disclosed techniques ensure that different types of interfaces can adhere to different types of constraints, allowing the component being optimized to retain a desired function within a larger assembly. Another technical advantage of the disclosed techniques is that the boundary between the constrained interface and the free-form region is updated in a method that produces a smooth, gradual transition rather than an abrupt change in geometry, which further improves the optimized component. These technical advantages provide one or more technological advancements over prior art approaches.
1. In some embodiments, a computer-implemented method for optimizing a shape of a component comprises simulating a state of a current shape of the component, calculating a sensitivity of an objective function for the shape with respect to modifications to the current shape based on the simulated state, generating a source function for an optimization equation based on the sensitivity, adding one or more constraint terms to the optimization equation to generate a constrained optimization equation, solving the constrained optimization equation to generate a solution to the constrained optimization equation, updating a velocity field based on the solution to the constrained optimization equation, solving a transport function based on the updated velocity field to generate a solution of the transport equation, and updating the current shape based on the solution to the transport equation to generate an updated shape.
2. The computer implemented method of clause 1, wherein the one or more constraint terms are based on one or more constraints on an interface of the current shape to generate the constrained optimization equation.
3. The computer-implemented method of clauses 1 or 2, wherein each of the one or more constraints is an affine constraint.
4. The computer-implemented method of any of clauses 1-3, wherein the one or more constraints allow one or more of a translation to a position of the interface, a rotation to an orientation of the interface, or a scaling of a size of the interface.
5. The computer-implemented method of any of clauses 1-4, wherein simulating the state of the current shape comprises applying a load to the component.
6. The computer-implemented method of any of clauses 1-5, wherein generating the source function comprises evaluating a shape derivative of the objective function at boundaries of the current shape.
7. The computer-implemented method of any of clauses 1-6, wherein the one or more constraint terms select a subset of possible velocity fields that satisfy the one or more constraints.
8. The computer-implemented method of any of clauses 1-7, wherein adding the one or more constraint terms to the optimization equation comprises adding one or more penalty terms to the objective function to generate a constrained Hilbert space extension residual.
9. The computer-implemented method of any of clauses 1-8, wherein calculating the sensitivity of the objective function comprises considering only components of the one or more modifications that are normal to a boundary of the current shape.
10. The computer-implemented method of any of clauses 1-9, wherein the updated velocity field is both time and space dependent.
11. The computer-implemented method of any of clauses 1-10, further comprising iteratively updating the current shape to generate further updated shapes until the updated shapes converge.
12. The computer-implemented method of any of clauses 1-11, wherein the shape converges when a change in the objective function over two consecutive iterations is below a threshold, or a difference between a level-set function describing the current shape between two consecutive iterations is less than a tolerance, or a magnitude of the updated velocity field is below a velocity threshold.
13. The computer-implemented method of any of clauses 1-12, wherein the current shape is described using a level-set function.
14. In some embodiments, one or more non-transitory computer readable media store instructions that, when executed by one or more processors, cause the one or more processors to optimize a shape of a component, by performing the operations of simulating a state of a current shape of the component, calculating a sensitivity of an objective function for the current shape with respect to shape modifications based on the simulated state, generating a source function for an optimization equation based on the sensitivity, adding one or more constraint terms to the optimization equation to generate a constrained optimization equation, solving the constrained optimization equation to generate a solution to the constrained optimization equation, updating a velocity field based on the solution to the constrained optimization equation, solving a transport function based on the updated velocity field to generate a solution of the transport equation, and updating the current shape based on the solution to the transport equation to generate an updated shape.
15. The one or more non-transitory computer readable media of clause 14, wherein the one or more constraint terms are based on one or more constraints on an interface of the current shape to generate a constrained optimization equation.
16. The one or more non-transitory computer readable media of clauses 14 or 15, wherein each of the one or more constraints is an affine constraint.
17. The one or more non-transitory computer readable media of any of clauses 14-16, wherein the one or more constraint terms select a subset of possible velocity fields that satisfy the one or more constraints.
18. The one or more non-transitory computer readable media of any of clauses 14-17, wherein calculating the sensitivity of the objective function comprises considering only components of the one or more modifications that are normal to a boundary of the current shape.
19. The one or more non-transitory computer readable media of any of clauses 14-18, wherein the updated velocity field is both time and space dependent.
20. In some embodiments, a computer system comprises one or more memories that include instructions, and one or more processors that are coupled to the one or more memories and, when executing the instructions, are configured optimize a shape of a component, by performing the operations of simulating a state of a current shape of the component, calculating a sensitivity of an objective function with respect to shape modifications for the current shape based on the simulated state, generating a source function for an optimization equation based on the sensitivity, adding one or more constraint terms to the optimization equation based on one or more constraints on an interface of the shape to generate a constrained optimization equation, solving the constrained optimization equation to generate a solution to the constrained optimization equation, updating a velocity field based on the solution to the constrained optimization equation, solving a transport function based on the updated velocity field to generate a solution of the transport equation, and updating the current shape based on the solution to the transport equation to generate an updated shape.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The invention has been described above with reference to specific embodiments. Persons of ordinary skill in the art, however, will understand that various modifications and changes may be made thereto without departing from the broader spirit and scope of the invention as set forth in the appended claims. For example, and without limitation, although many of the descriptions herein refer to specific types of I/O devices that may acquire data associated with an object of interest, persons skilled in the art will appreciate that the systems and techniques described herein are applicable to other types of I/O devices. The foregoing description and drawings are, accordingly, to be regarded in an illustrative rather than a restrictive sense.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for optimizing a shape of a component, the method comprising:
simulating a state of a current shape of the component;
calculating a sensitivity of an objective function for the shape with respect to modifications to the current shape based on the simulated state;
generating a source function for an optimization equation based on the sensitivity;
adding one or more constraint terms to the optimization equation to generate a constrained optimization equation;
solving the constrained optimization equation to generate a solution to the constrained optimization equation;
updating a velocity field based on the solution to the constrained optimization equation;
solving a transport function based on the updated velocity field to generate a solution of the transport equation; and
updating the current shape based on the solution to the transport equation to generate an updated shape.

2. The computer implemented method of claim 1, wherein the one or more constraint terms are based on one or more constraints on an interface of the current shape to generate the constrained optimization equation.

3. The computer-implemented method of claim 2, wherein each of the one or more constraints is an affine constraint.

4. The computer-implemented method of claim 2, wherein the one or more constraints allow one or more of a translation to a position of the interface, a rotation to an orientation of the interface, or a scaling of a size of the interface.

5. The computer-implemented method of claim 1, wherein simulating the state of the current shape comprises applying a load to the component.

6. The computer-implemented method of claim 1, wherein generating the source function comprises evaluating a shape derivative of the objective function at boundaries of the current shape.

7. The computer-implemented method of claim 1, wherein the one or more constraint terms select a subset of possible velocity fields that satisfy the one or more constraints.

8. The computer-implemented method of claim 1, wherein adding the one or more constraint terms to the optimization equation comprises adding one or more penalty terms to the objective function to generate a constrained Hilbert space extension residual.

9. The computer-implemented method of claim 1, wherein calculating the sensitivity of the objective function comprises considering only components of the one or more modifications that are normal to a boundary of the current shape.

10. The computer-implemented method of claim 1, wherein the updated velocity field is both time and space dependent.

11. The computer-implemented method of claim 1, further comprising iteratively updating the current shape to generate further updated shapes until the updated shapes converge.

12. The computer-implemented method of claim 11, wherein the shape converges when:
a change in the objective function over two consecutive iterations is below a threshold; or
a difference between a level-set function describing the current shape between two consecutive iterations is less than a tolerance; or
a magnitude of the updated velocity field is below a velocity threshold.

13. The computer-implemented method of claim 1, wherein the current shape is described using a level-set function.

14. One or more non-transitory computer readable media storing instructions that, when executed by one or more processors, cause the one or more processors to optimize a shape of a component, by performing the operations of:
simulating a state of a current shape of the component;
calculating a sensitivity of an objective function for the current shape with respect to shape modifications based on the simulated state;
generating a source function for an optimization equation based on the sensitivity;
adding one or more constraint terms to the optimization equation to generate a constrained optimization equation;
solving the constrained optimization equation to generate a solution to the constrained optimization equation;
updating a velocity field based on the solution to the constrained optimization equation;
solving a transport function based on the updated velocity field to generate a solution of the transport equation; and
updating the current shape based on the solution to the transport equation to generate an updated shape.

15. The one or more non-transitory computer readable media of claim 14, wherein the one or more constraint terms are based on one or more constraints on an interface of the current shape to generate a constrained optimization equation.

16. The one or more non-transitory computer readable media of claim 15, wherein each of the one or more constraints is an affine constraint.

17. The one or more non-transitory computer readable media of claim 15, wherein the one or more constraint terms select a subset of possible velocity fields that satisfy the one or more constraints.

18. The one or more non-transitory computer readable media of claim 14, wherein calculating the sensitivity of the objective function comprises considering only components of the one or more modifications that are normal to a boundary of the current shape.

19. The one or more non-transitory computer readable media of claim 14, wherein the updated velocity field is both time and space dependent.

20. A computer system, comprising:
one or more memories that include instructions; and
one or more processors that are coupled to the one or more memories and, when executing the instructions, are configured optimize a shape of a component, by performing the operations of:
simulating a state of a current shape of the component;
calculating a sensitivity of an objective function with respect to shape modifications for the current shape based on the simulated state;
generating a source function for an optimization equation based on the sensitivity;
adding one or more constraint terms to the optimization equation based on one or more constraints on an interface of the shape to generate a constrained optimization equation;
solving the constrained optimization equation to generate a solution to the constrained optimization equation;
updating a velocity field based on the solution to the constrained optimization equation;
solving a transport function based on the updated velocity field to generate a solution of the transport equation; and
updating the current shape based on the solution to the transport equation to generate an updated shape.
